(19) United States
(12) Patent Application Publication
(10) Pub. No.: US 2026/0173557 A1
(43) Pub. Date: Jun. 18, 2026

(54) IMAGE SENSOR

(71) Applicant: OMNIVISION TECHNOLOGIES, INC., Santa Clara, CA (US)

(72) Inventors: Xiaodong Yang, San Jose, CA (US); Chengming Liu, Fremont, CA (US); Rui Ke, San Jose, CA (US); Wenchao Zhang, Fremont, CA (US); Youming Ding, San Jose, CA (US); Liangyu Xu, San Jose, CA (US); Masayu Higuchi, Tokyo (JP)

(73) Assignee: OMNIVISION TECHNOLOGIES, INC., Santa Clara, CA (US)

(21) Appl. No.: 18/984,851

(22) Filed: Dec. 17, 2024

(51) Int. Cl. H10F 39/00; H10F 39/18

(52) U.S. Cl. CPC H10F 39/8063; H10F 39/182

(57) ABSTRACT

An image sensor provided herein includes a first pixel group and a second pixel group. The first pixel group includes a first photodiode array including photodiodes to generate a first color data; and first microlenses, wherein each of the first microlenses is disposed overlaying n of the photodiodes in the first photodiode array. The second pixel group is located next to the first pixel and includes a second photodiode array including photodiodes to generate a second color data representing a different color from the first color data; and second microlenses, wherein each of the second microlenses is disposed overlaying m of the photodiodes in the second photodiode array, n and m are integers, and at least one of n and m is greater than 1.

### BACKGROUND

### Technical Field

The disclosure is related to an image sensor.

### Description of Related Art

Image sensors have become ubiquitous and are now widely used in digital cameras, cellular phones, security cameras, as well as in medical, automotive, and other applications. As image sensors are integrated into a broader range of electronic devices, it is desirable to enhance their functionality, performance metrics, and the like in as many ways as possible (e.g., resolution, power consumption, dynamic range) through both device architecture design as well as image acquisition processing. The technology used to manufacture image sensors has continued to advance at a great pace. For example, the demands of higher resolution and lower power consumption have encouraged the further miniaturization and integration of these devices.

An image sensor includes an array of pixels that are implemented by photosensitive components such as photodiodes and certain optical structures such as color filters, microlenses, or a combination thereof. In one implement, each photodiode is covered by one microlens, which achieves high resolution of the sensed image. However, such design fails to autofocus and thus the image sensor required to be improved.

### BRIEF DESCRIPTION OF THE DRAWINGS

FIG. 1 is a schematic diagram of an image sensor in accordance with an embodiment of the disclosure.

FIG. 2 is a schematic diagram of an image sensor in accordance with an embodiment of the disclosure.

FIG. 3 is a schematic diagram of an image sensor in accordance with an embodiment of the disclosure.

FIG. 4 is a schematic diagram of an image sensor in accordance with an embodiment of the disclosure.

FIG. 5 is a schematic diagram of an image sensor in accordance with an embodiment of the disclosure.

FIG. 6 is a schematic diagram of an image sensor in accordance with an embodiment of the disclosure.

FIG. 7 is a schematic diagram of an image sensor in accordance with an embodiment of the disclosure.

FIG. 8 is a schematic diagram of an image sensor in accordance with an embodiment of the disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention.

### DESCRIPTION OF THE EMBODIMENTS

References throughout this specification to one implementation, an implementation, one embodiment, an embodiment, and/or the like means that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has always been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers at least to the context of the present patent application.

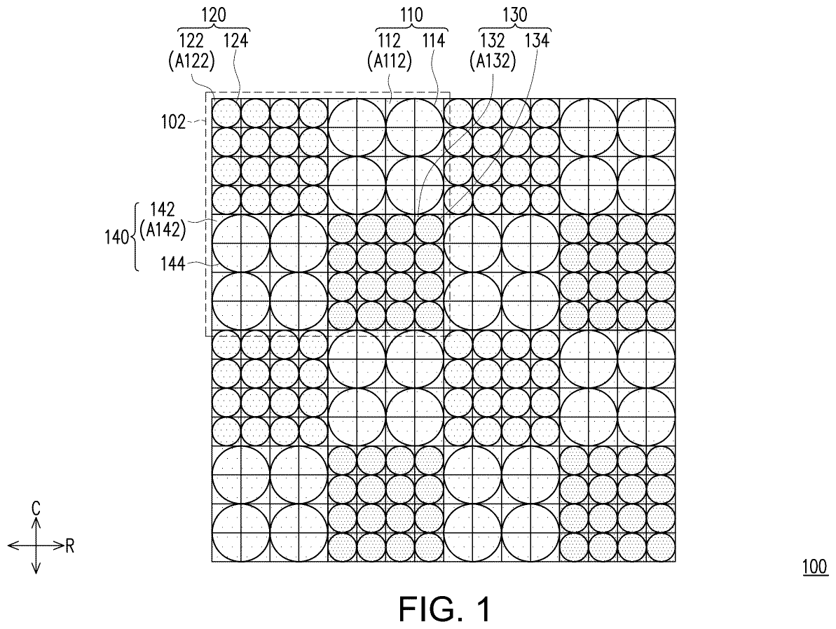

FIG. 1 is a schematic diagram of an image sensor in accordance with an embodiment of the disclosure. An image sensor 100 includes at least a first pixel group 110 and a second pixel group 120 located next to the first pixel group 110 in a row direction R. The image sensor 100 may further include other pixel groups, such as a third pixel group 130 located next to the first pixel group 110 in the column direction C and a fourth pixel group 140 located next to the second pixel group 120 in the column direction C. In addition, the first pixel group 110, the second pixel group 120, the third pixel group 130 and the fourth pixel group 140 may be arranged in a 2×2 array to serve as a repeating unit 102. The image sensor 100 includes a plurality of repeating units 102 arranged in an array in the column direction C and the row direction R and each of the repeating units 102 may be implemented to form a Bayer pattern. For example, the first pixel group 110 and the fourth pixel group 140 arranged diagonally may be green pixel groups, while one of the second pixel group 120 and the third pixel group 130 is a red pixel group and the other of the second pixel group 120 and the third pixel group 130 is a blue pixel group, but the disclosure is not limited thereto. Each of the repeating units 102 may be implemented by a common configuration and the following descriptions depict one repeating unit 102 for a descriptive purpose.

A pixel group includes a plurality of pixels. Each pixel has a photodiode. The first pixel group 110 includes a first photodiode array A112 and first microlenses 114. The first photodiode array A112 includes photodiodes 112 configured to generate first color data. For example, the first color data may represent green. In some embodiments, each of the photodiodes 112 in the first photodiode array A112 may be implemented by a first color filter disposed on a photodiode structure. The first microlenses 114 are disposed overlaying the photodiodes 112 of the first photodiode array A112. In the embodiment, a quantity of the first microlenses 114 is less than a quantity of the photodiodes 112. Herein, each of the first microlenses 114 is disposed overlaying n of the photodiodes 112 in the first photodiode array A112 and n is an integer greater than 1. For example, n is 4 and every four photodiodes 112 in the first photodiode array A112 share one of the first microlenses 114. Each of the first microlenses 114 has an isotropic shape in a top view. In some embodiments, the photodiodes 112 under one of the first microlenses 114 may be binned to generate the color data, but the disclosure is not limited thereto. In the embodiment, a quantity of the photodiodes 112 in the first photodiode array A112 is 16, and the 16 photodiodes 112 are arranged in a 4×4 array in the row direction R and the column direction C. In addition, a quantity of the first microlenses 114 in one first pixel group 110 is 4 and the four first microlenses 114 are arranged in a 2×2 array in the row direction R and the column direction C.

One of the first microlenses 114 overlaying four photodiodes 112 serves an implement of quad photodiodes (QPD) configuration. In the embodiment, a phase detection autofocus (PDAF) may be performed by comparing the electrical signals between adjacent photodiodes 112 included in the QPD configuration and further comparing the electrical signals between diagonal photodiodes 112 included in QPD configuration to determine the degree of autofocus needed for the image of interest. Therefore, the image sensor 100 provides the PDAF function for a rapid autofocus requirement.

The second pixel group 120 includes a second photodiode array A122 and second microlenses 124. In the embodiment, the photodiodes 122 of the second photodiode array A122 are configured to generate second color data that represents a different color from the first color data generated by the first photodiode array A112. In some embodiments, the second photodiode array A122 generates the second color data representing blue or red while the first photodiode array A112 generates the first color data representing green. In the embodiment, the quantity of the second microlenses 124 is the same as the photodiodes 122 in the second photodiode array A122. Specifically, each of the second microlenses 124 is disposed overlaying m of the photodiodes 122 in the second photodiode array A122 and m is 1 which is different from n in the design of the first pixel group 110. The second microlenses 124 and the photodiodes 122 are arranged in a one-to-one configuration, in which each microlens 124 overlaps one single photodiode 122. Under the one-to-one configuration, each photodiode 122 provides full-resolution image data, which helps to achieve a high resolution image.

The third pixel group 130 is next to the first pixel group 110 in the column direction C while the second pixel group 120 is next to the first pixel group 110 in the row direction C. Therefore, the second pixel group 120 and the third pixel group 130 are next to different sides of the first pixel group 110. The second pixel group 120 and the third pixel group 130 are arranged diagonally in the repeating unit 102. The third pixel group 130 includes a third photodiode array A132 and third microlenses 134. The photodiodes 132 of the third photodiode array A132 are configured to generate third color data representing a different form the first color data generated by the first photodiode array A112 and the second color data generated by the second photodiode array A122. In some embodiments, the first color data represents green, one of the second color data and the third color data represents blue and the other of the third color data represents red. In the embodiment, the third photodiode array A132 and the third microlenses 134 may be implemented by a configuration substantially the same as the second pixel group 120. For example, each of the third microlenses 134 is disposed overlaying 1 photodiode 132 in the third photodiode array A132. Therefore, similar to the design of the second pixel group 120, the photodiodes 132 in the third photodiode array A132 and the third microlenses 134 are arranged in a one-to-one configuration, which helps to achieve a high resolution of the sensed image.

The fourth pixel group 140 in the embodiment is located next to the second pixel group 120 in the column direction C and next to the third pixel group 130 in the row direction R, and the fourth pixel group 140 and the first pixel group 110 are arranged diagonally in the repeating unit 102. The fourth pixel group 140 may have substantially the same configuration as the first pixel group 110. Specifically, the fourth pixel group 140 includes a fourth photodiode array A142 and fourth microlenses 144. The fourth photodiode array A142 includes photodiodes 142 configured to generate fourth color data representing the same color as the first photodiode array A112. Each of the fourth microlenses 144 is disposed overlaying n of the photodiodes 142 in the fourth photodiode array A142 and n is an integer greater than 1; for example, n is 4 in the embodiment. In some embodiments, the photodiodes 142 under one of the fourth microlenses 144 may be binned to generate the color data. The first pixel group 110 and the fourth pixel group 140 are green pixel groups. Therefore, the repeating unit 102 includes two green pixel groups (the first pixel group 110 and the fourth pixel group 140), one blue pixel group (one of the second pixel group 120 and the third pixel group 130) and one red pixel group (the other of the second pixel group 120 and the third pixel group 130).

In the embodiment, each repeating unit 102 of the image sensor 100 includes four pixel groups arranged in a 2×2 array. Among the four pixel groups, the first pixel group 110 and the fourth pixel group 140 are implemented in the QPD configuration so that the autofocus function is achieved by performing PDAF, and the second pixel group 120 and the third pixel group 130 are implemented by one photodiode-to-one microlens configuration (also known as 4C or 4 Cells configuration) to obtain a high resolution of sensed image. In addition, in the repeating unit 102 of the image sensor 100, the arrangement of the microlenses may be point symmetry so that the microlens arrangement at the upper-right portion of the repeating unit 102 is the same as the microlens arrangement at the lower-left portion of the repeating unit 102 and the microlens arrangement at the upper-left portion of the repeating unit 102 is the same as the microlens arrangement at the lower-right portion of the repeating unit 102.

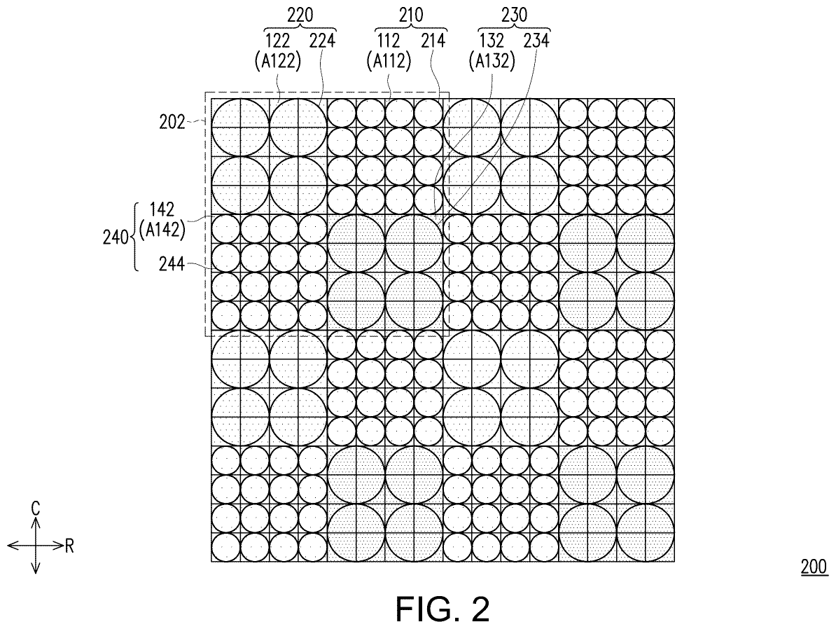

FIG. 2 is a schematic diagram of an image sensor in accordance with an embodiment of the disclosure. An image sensor 200 at least includes a first pixel group 210 and a second pixel group 220. Each of the first pixel group 210 and the second pixel group 220 includes an array of photodiodes and corresponding microlenses, in which photodiodes in one pixel group are configured to sense a prescribed wavelength range of an incident electromagnetic wave, e.g. a specific color of an incident light passing through the corresponding microlenses.

The first pixel group 210 includes a first photodiode array A112 having a plurality of photodiodes 112 generating first color data and first microlenses 214. The first photodiode array A112 includes 16 photodiodes 112 arranged in a 4×4 array and the 16 photodiodes 112 are, for example, configured to sense green color of the incident light. Each of the first microlenses 214 may be disposed overlaying n of the photodiodes 112 in the first photodiode array A112. In the embodiment, n is 1 and the first microlenses 214 are corresponding to the photodiodes 112 in the first photodiode array A112 in a one-to-one configuration. In some embodiments, each of the first microlenses 214 is located over and aligned with one of the photodiodes 112 such that each of the photodiodes 112 receives the incident light at all angles to achieve a full resolution sensing.

The second pixel group 220 includes a second photodiode array A122 including a plurality of photodiodes 122 configured to generate a second color date and second microlenses 224. The second photodiode array A122 includes 16 photodiodes 122 arranged in a 4×4 array and the 16 photodiodes 122 are, for example, configured to sense blue color of the incident light. Each of the second microlenses 224 is disposed overlaying m of the photodiodes 122 in the second photodiode array A122. In the embodiment, m is 4 and thus four photodiodes 122 share one second microlenses 224. In some embodiments, the photodiodes 122 under one of the second microlenses 224 may be binned to generate the color data. In the embodiment, the photodiodes 122 in the second photodiode array A122 and the photodiodes 112 in the first photodiode array A112 are arranged in a substantially common pitch, and each of the second microlenses 224 has a greater diameter than each of the first microlenses 214 for overlaying four photodiodes 114. Specifically, each of the second microlenses 224 may have a circular top-view shape located within an area of the photodiodes 122 arranged in a 2×2 array. Herein, each of the second microlenses 224 and the corresponding four photodiodes 122 are implemented by a quad photodiodes (QPD) configuration. Each of the photodiodes 122 overlaps a portion of the corresponding second microlens 224 and receives the incident light from a certain angle range. A phase detection autofocus (PDAF) may be performed by comparing the electrical signals between photodiodes 122 included in the QPD configuration. Therefore, the second pixel group 220 having QPD configuration helps to achieve the auto-focus function of the image sensor 200.

The image sensor 200 may further include a third pixel group 230. The third pixel group 230 may have the same configuration as the second pixel group 220. Specifically, the third photodiode array A132 includes photodiodes 132 configured to generate third color data and third microlenses 234 overlaying the third photodiode array A132. The third color data generated by the third photodiode array A132 represent a different color from the second color data generated by the second photodiode array A122 and the first color data generated by the first photodiode array A112. For example, the third color data generated by the third photodiode array A132 represents red, the second color data generated by the second photodiode array A122 represents blue and the first color data generated by the first photodiode array A112 represents green. Each of the third microlenses 234 is disposed overlaying p of photodiodes 132 of the third photodiode array A132 and p is 4 in the embodiment. In some embodiments, the photodiodes 132 under one of the third microlenses 234 may be binned to generate the color data. Similar to the second microlenses 224, each of the third microlenses 234 is shared by four photodiodes 132 arranged in a 2×2 array to form a QPD configuration. The third pixel group 230 enables the PDAF as the second pixel group 220.

The image sensor 200 further includes a fourth pixel group 240 that may have the same configuration as the first pixel group 210. The fourth pixel group 240 includes a fourth photodiode array A142 and fourth microlenses 244. The photodiodes 142 in the fourth photodiode array A142 generate fourth color data representing the same color as the first color data generated by the first photodiode array A112. For example, the fourth color data represents green. In the embodiment, the quantity of the fourth microlenses 244 is the same as the photodiodes 142 in the fourth photodiode array A142, e.g. 16 in the embodiment. Each of the fourth microlenses 244 covers and overlaps one photodiode 142. Accordingly, the fourth pixel group 240 enables a full resolution sensing.

In the embodiment, the first pixel group 210, the second pixel group 220, the third pixel group 230 and the fourth pixel group 240 in the image sensor 200 are arranged in a 2×2 array to form a repeating unit 202, and the image sensor 200 may include a plurality of the repeating units 202 arranged in array. In each repeating unit 202, the first pixel group 210 and the fourth pixel group 240 are used to generate the color data representing the same color, e.g. green, and are arranged diagonally. Simultaneously, the second pixel group 220 and the third pixel group 230 are used to generate the color data represent another two colors, e.g. blue and red, respectively, and are arranged diagonally. In the embodiment, the arrangement of the first pixel group 210, the second pixel group 220, the third pixel group 230 and the fourth pixel group 240 follows a Bayer pattern, but the disclosure is not limited thereto.

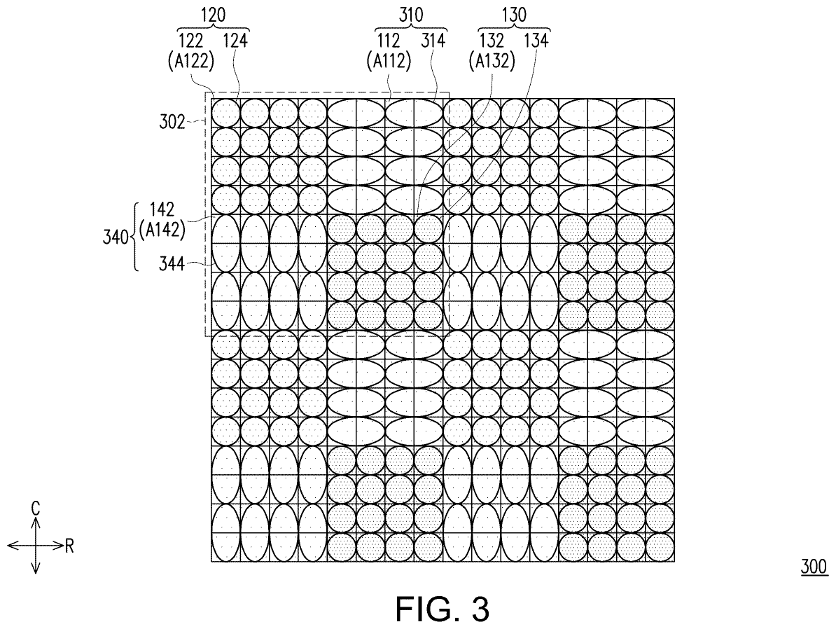

FIG. 3 is a schematic diagram of an image sensor in accordance with an embodiment of the disclosure. An image sensor 300 shown in FIG. 3 includes a plurality of repeating unit 302 and each repeating unit 302 includes a first pixel group 310, a second pixel group 120, a third pixel group 130 and a fourth pixel group 340 arranged in a 2×2 array. Each of the repeating unit 302 may be implemented by a Bayer pattern. For example, the first pixel group 310 and the four pixel group 340 diagonally arranged are used to generate the color data of green, while the second pixel group 120 and the third pixel group 130 diagonally arranged are used to generate the color data of blue and red, respectively.

In the embodiment, the first pixel group 310 includes a first photodiode array A112 and first microlenses 314. The first photodiode array A112 may be implemented by the same design as previous embodiments, and thus not reiterated herein. Each of the first microlenses 314 is disposed overlaying n of the photodiodes 112 in the first photodiode array A112 and n is 2 in the embodiment. Specifically, two photodiodes 112 share one first microlens 314 in the embodiment. Each of the first microlenses 314 has an elongated shape in a top view. In the embodiment, the first microlens 314 are oriented in parallel with each other and are substantially in parallel with the row direction R. Accordingly, each of the first microlens 314 overlaps 1 (row)×2 (column) photodiodes 112. In the first pixel group 310 having 16 photodiodes 112 arranged in a 4×4 array, four of the first microlenses 314 are arranged in a column and two columns of the first microlenses 314 are included to cover the 16 photodiodes 112.

The second pixel group 120 and the third pixel group 130 are implemented by the same design as the second pixel group 120 and the third pixel group 130 depicted in FIG. 1. Therefore, the disposition relationship and the configuration of the second pixel group 120 and the third pixel group 130 may refer to the previous descriptions and are not reiterated herein. Specifically, the second pixel group 120 includes a second photodiode array A122 and second microlenses 124, the third pixel group 130 includes a third photodiode array A132 and third microlenses 134, and each of the second pixel group 120 and the third pixel group 130 is implemented by arranging the photodiodes and the microlenses in a one-to-one configuration. Accordingly, each of the second pixel group 120 and the third pixel group 130 enables a full resolution sensing.

The fourth pixel group 340 in the embodiment includes a fourth photodiode array A142 and fourth microlenses 344. The fourth photodiode array A142 is used for generating fourth color data representing the same color as the first color data generated by the first photodiode array A112. For example, the fourth photodiode array A142 is used for generating a fourth color data representing green. In the embodiment, each of the fourth microlenses 344 is disposed overlaying n of the photodiodes 142 in the fourth photodiode array A142 and n is 2. The relationship in the quantity of photodiodes and the quantity of microlenses in the fourth pixel group 340 is the same as the first pixel group 310. However, the arrangements of the microlenses in the first pixel group 310 and the fourth pixel group 340 are different.

In the fourth pixel group 340, each of the fourth microlenses 344 is oriented in parallel to each other and in parallel to the column direction C. Each of the fourth microlens 344 overlaps 2 (row)×1 (column) photodiodes 142. In other words, corresponding to the fourth photodiode array A142 arranged in a 4×4 array, two of the fourth microlenses 344 are arranged in one column and four columns of the fourth microlenses 344 are included. The orientations of the fourth microlenses 344 are substantially perpendicular to the orientation of the first microlenses 314. In some embodiments, the first microlenses 314 and the fourth microlenses 344 enable PDAF at different directions.

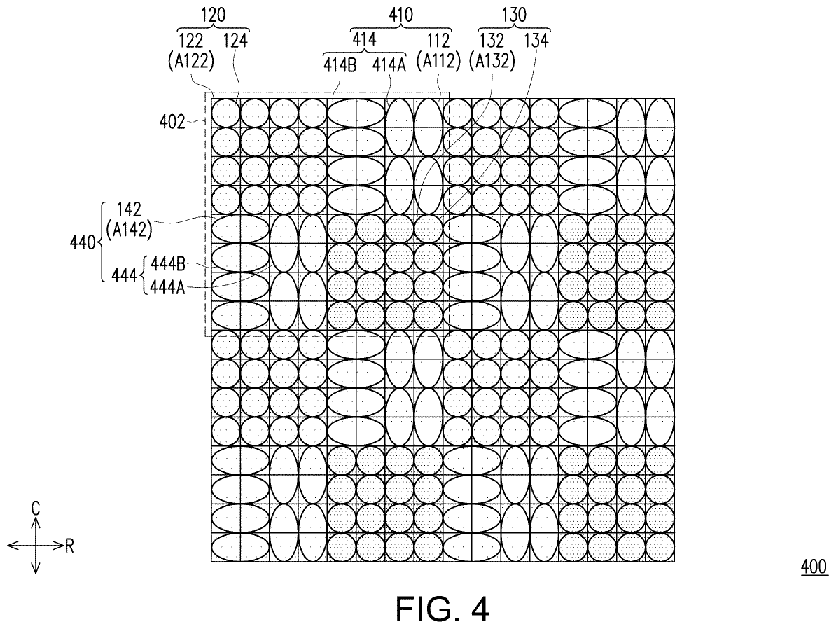

FIG. 4 is a schematic diagram of an image sensor in accordance with an embodiment of the disclosure. An image sensor 400 shown in FIG. 4 includes a plurality of repeating unit 402 and each repeating unit 402 includes a first pixel group 410, a second pixel group 120, a third pixel group 130 and a fourth pixel group 440 arranged in a 2×2 array. Each of the repeating unit 402 may be implemented by a Bayer pattern. For example, the first pixel group 410 and the four pixel group 440 diagonally arranged are used to generate the color data of green, while the second pixel group 120 and the third pixel group 130 diagonally arranged are used to generate the color data of blue and red, respectively.

In the embodiment, the second pixel group 120 and the third pixel group 130 are implemented by the same design as the second pixel group 120 and the third pixel group 130 depicted in FIG. 1. Therefore, the disposition relationship and the configuration of the second pixel group 120 and the third pixel group 130 may refer to the previous descriptions and are not reiterated herein. Specifically, the second pixel group 120 includes a second photodiode array A122 and second microlenses 124, the third pixel group 130 includes a third photodiode array A132 and third microlenses 134, and each of the second pixel group 120 and the third pixel group 130 is implemented by arranging the photodiodes and the microlens in a one-to-one configuration. Accordingly, each of the second pixel group 120 and the third pixel group 130 enables a full resolution sensing.

The first pixel group 410 includes a first photodiode array A112 and first microlenses 414 overlaying the first photodiode array A112. The first photodiode array A112 include 16 photodiodes 112 arranged in a 4×4 array and each of the first microlenses 412 is disposed overlaying n of photodiodes 112 of the first photodiode array A112, in which n is 2 in the embodiment. The first microlenses 414 have elongated shapes and are arranged in a multiplexed orientation. For example, the first microlenses 414 includes a first portion of the first microlenses 414 (the first microlenses 414A) in a first orientation and a second portion of the first microlenses 414 (the first microlenses 414B) in a second orientation. Each of the first microlenses 414A is oriented substantially in parallel to the column direction C to cover 2 (row)×1 (column) photodiodes 112 while each of the first microlenses 414B is oriented substantially in parallel to the row direction R to cover 1 (row)×2 (column) photodiodes 112.

As shown in FIG. 4, two microlenses of the first microlenses 414A are arranged in one column and two columns of the first microlenses 414A are included in the first pixel group 410 to cover eight photodiodes 112 arranged in a 2×4 array. Four first microlenses 414B are included in the first pixel group 410 and the first microlenses 414B are arranged in one column to cover another eight photodiodes 112 arranged in a 2×4 array. In the embodiment, the second portion of the first microlenses 414 (the first microlenses 414B) is located between the first portion of the first microlenses 414 (the first microlenses 414A) and the second pixel group 402, but the disclosure is not limited thereto. In an alternative embodiment, the first portion of the first microlenses 414 (the first microlenses 414A) is optionally located between the second portion of the first microlenses 414 (the first microlenses 414B) and the second pixel group 402. In the first pixel group 410, the first portion of the first microlenses 414 (the first microlenses 414A) and the second portion of the first microlenses 414B (the first microlenses 414B) may enable PDAF at different directions.

The fourth pixel group 440 is implemented by the same design as the first pixel group 410. The fourth pixel group 440 includes a fourth photodiode array A142 and fourth microlenses 444. The fourth photodiode array A142 includes 16 photodiodes 142 arranged in a 4×4 array and each of the fourth microlenses 444 is disposed overlaying n of photodiodes 142 in the fourth photodiode array A142, in which n is 2. The fourth microlenses 444 includes a first portion of the fourth microlenses 444 (the fourth microlenses 444A) and a second portion of the fourth microlenses 444 (the fourth microlenses 444B). Each microlens of the fourth microlenses 444A is oriented in parallel to the column direction C and each microlens of the fourth microlenses 444B is oriented in parallel to the row direction R. Four microlenses of the first portion of the fourth microlenses 444 (the fourth microlenses 444A) are arranged in a 2×2 array to cover 2×4 photodiodes 142 in the fourth photodiode array A142. Four microlenses of the second portion of the fourth microlenses 444 (the fourth microlenses 444B) are arranged in a 1×4 array to cover another 2×4 photodiodes 142 in the fourth photodiode array A142. The first portion of the fourth microlenses 444 and the second portion of the fourth microlenses 444 are oriented in different directions to enable PDAF at different directions.

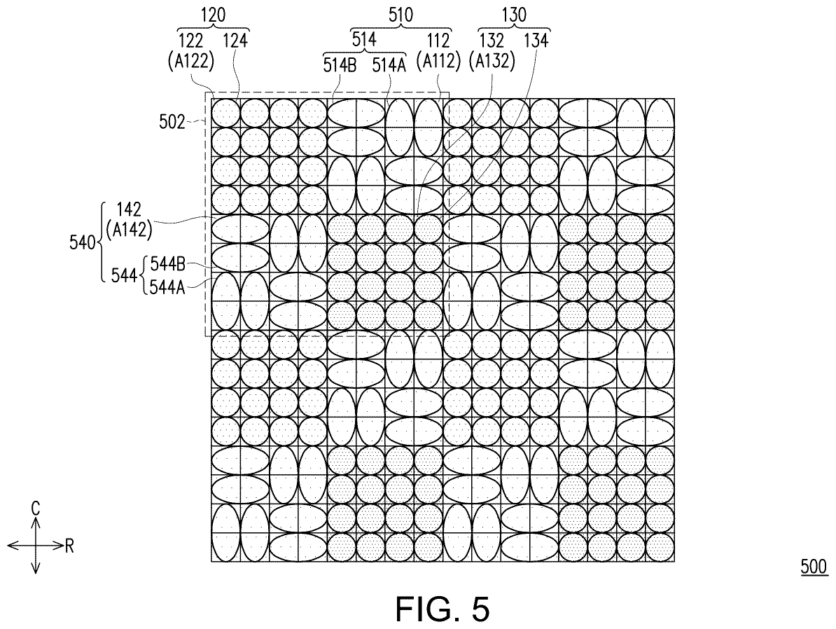

FIG. 5 is a schematic diagram of an image sensor in accordance with an embodiment of the disclosure. An image sensor 500 shown in FIG. 5 includes a plurality of repeating unit 502 and each repeating unit 502 includes a first pixel group 510, a second pixel group 120, a third pixel group 130 and a fourth pixel group 540 arranged in a 2×2 array. Each of the repeating unit 502 may be implemented by a Bayer pattern. For example, the first pixel group 510 and the four pixel group 540 diagonally arranged are used to generate the color data of green, while the second pixel group 120 and the third pixel group 130 diagonally arranged are used to generate the color data of blue and red, respectively. In the embodiment, the second pixel group 120 and the third pixel group 130 are implemented by the same design as the second pixel group 120 and the third pixel group 130 depicted in FIG. 1. For example, referring to the previous embodiment, the second pixel group 120 includes a second photodiode array A122 and second microlenses 124, and the third pixel group 130 includes a third photodiode array A132 and third microlenses 134, in which the photodiodes and the microlenses are arranged in a one-to-one configuration.

The first pixel group 510 includes a first photodiode array A112 and first microlenses 514. The first photodiode array A112 includes 16 photodiodes 112 arranged in a 4×4 array. The photodiodes 112 are configured to generate first color data representing green. Each of the first microlenses 514 is disposed overlaying n of the photodiodes 112 of the first photodiode array A112 and n is 2 in the embodiment. In some embodiments, the photodiodes 112 under one of the first microlenses 514 may be binned to generate the color data. Each of the first microlenses 514 has an elongated shape to overlap two photodiodes 112 in the first photodiode array A112. The first microlens 514 may be divided into a first portion of the first microlenses 514 (the first microlenses 514A) oriented in parallel to the column direction C and a second portion of the first microlenses 514 (the first microlenses 514B) oriented in parallel to the row direction R.

In the embodiment, first microlenses 514A includes four microlenses and the first microlenses 514B also includes four microlenses. The first microlenses 514A and the first microlenses 514B may be alternately arranged in the row direction R and the column direction C. Two microlenses of the first microlenses 514A are located at the upper-right portion of the first pixel group 510 and two microlenses of the first microlenses 514B are located at the lower-right portion of the first pixel group 510. Simultaneously, the other two microlenses of the first microlenses 514A are located at the lower-left portion of the first pixel group 510 and the other two microlenses of the first microlenses 514B are located at the upper-left portion of the first pixel group 510. For example, two microlenses of the first microlenses 514A in the upper-right portion of the first pixel group 510 and two microlenses of the first microlenses 514B in the lower-right portion of the first pixel group 510 are alternately arranged in the column direction C. Two microlenses of the first microlenses 514A in the upper-right portion of the first pixel group 510 and two microlenses of the first microlenses 514B in the upper-left portion of the first pixel group 510 are alternately arranged in the row direction R. Two microlenses of the first microlenses 514A in the lower-left portion of the first pixel group 510 and two microlenses of the first microlenses 514B in the upper-left portion of the first pixel group 510 are alternately arranged in the column direction C. In addition, two microlenses of the first microlenses 514A in the lower-left portion of the first pixel group 510 and two microlenses of the first microlenses 514B in the lower-right portion of the first pixel group 510 are alternately arranged in the row direction R.

The fourth pixel group 540 includes a fourth photodiode array A142 and fourth microlenses 544. The fourth photodiode array A142 includes 16 photodiodes 142 arranged in a 4×4 array and each of the fourth microlenses 544 is disposed overlaying 2 of the photodiodes 142 of the fourth photodiode array A142. The arrangement of the fourth microlenses 544 is substantially the same as the arrangement of the first microlenses 514 in the first pixel group 510. Specifically, the fourth microlenses 544 includes a first portion of the fourth microlenses 544 (the fourth microlenses 544A) oriented in parallel to the column direction C and a second portion of the fourth microlenses 544 (the fourth microlenses 544B) oriented in parallel to the row direction R. The fourth microlenses 544A and the fourth microlenses 544B are alternately arranged in both the column direction C and the row direction R. As shown in FIG. 5, two microlenses of the fourth microlenses 544A are grouped and two groups of the microlenses of the fourth microlenses 544A are diagonally arranged, while two microlenses of the fourth microlenses 544B are grouped and two groups of the microlenses of the fourth microlenses 544B are diagonally arranged.

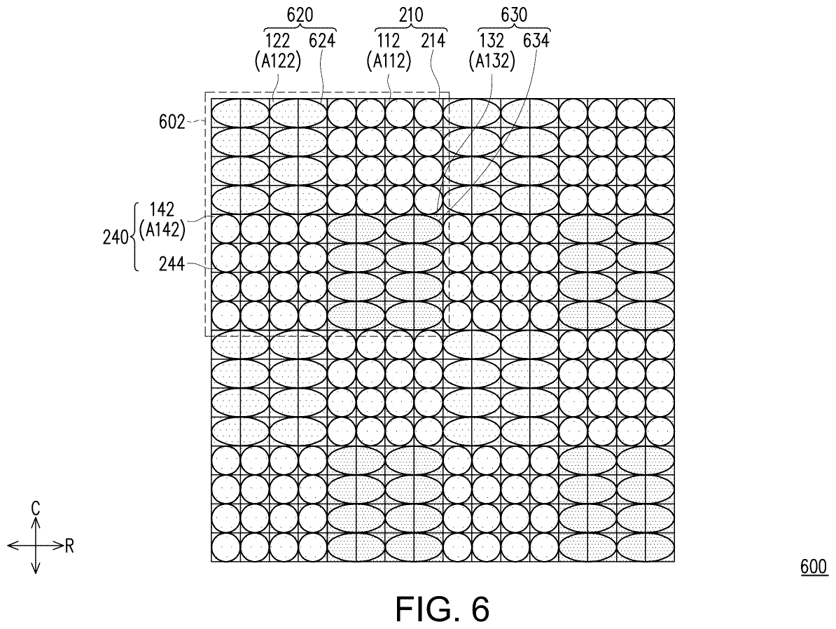

FIG. 6 is a schematic diagram of an image sensor in accordance with an embodiment of the disclosure. An image sensor 600 shown in FIG. 6 includes a plurality of repeating unit 602 and each repeating unit 602 includes a first pixel group 210, a second pixel group 620, a third pixel group 630 and a fourth pixel group 240 arranged in a 2×2 array. Each of the repeating unit 602 may be implemented by a Bayer pattern. For example, the first pixel group 210 and the four pixel group 240 diagonally arranged are used to generate the color data of green, while the second pixel group 620 and the third pixel group 630 diagonally arranged are used to generate the color data of blue and red, respectively. In the embodiment, the first pixel group 210 and the fourth pixel group 240 are implemented by the same design as the first pixel group 210 and the fourth pixel group 240 depicted in FIG. 2. For example, referring to the previous embodiment, the first pixel group 110 includes a first photodiode array A112 and first microlenses 214 and the fourth pixel group 240 includes a fourth photodiode array A142 and fourth microlenses 244, in which the photodiodes and the microlenses are arranged in a one-to-one configuration. The designs and the dispositions of the first pixel group 210 and the fourth pixel group 240 may refer to the previous description and be not reiterated herein.

The second pixel group 620 includes a second photodiode array A122 and second microlenses 624 overlaying the second photodiode array A122. The second photodiode array A122 includes 4×4 photodiodes 122 and each of the second microlenses 624 is disposed overlaying m of the photodiodes 122 in the second photodiode array A122, in which m is 2 in the embodiment. Each of the second microlenses 624 has an elongated shape and the second microlenses 624 are arranged in parallel to each other. For example, each of the second microlenses 624 is oriented in parallel to the row direction R. As shown in FIG. 6, each four microlenses of the second microlenses 624 are arranged in a column to overlap 2×4 photodiodes 122 and two columns of the second microlenses 624 are disposed within the second pixel group 620.

The third pixel group 630 is implemented in the same design as the second pixel group 620, but the two pixel groups are used for generating color data representing different colors. Specifically, the third pixel group 620 includes a third photodiode array A132 and third microlenses 634 overlaying the third photodiode array A132. The third photodiode array A132 includes 16 photodiodes 132 arranged in a 4×4 array and each of the third microlenses 634 is disposed overlaying 2 of the photodiodes 132 in the third photodiode array A132. Each of the third microlenses 634 is oriented in parallel to the row direction R to overlap 1 (row)×2 (column) photodiodes 132 in the third photodiode array A132. As shown in FIG. 6, the third microlenses 634 are arranged in a 4 (row)×2 (column) array.

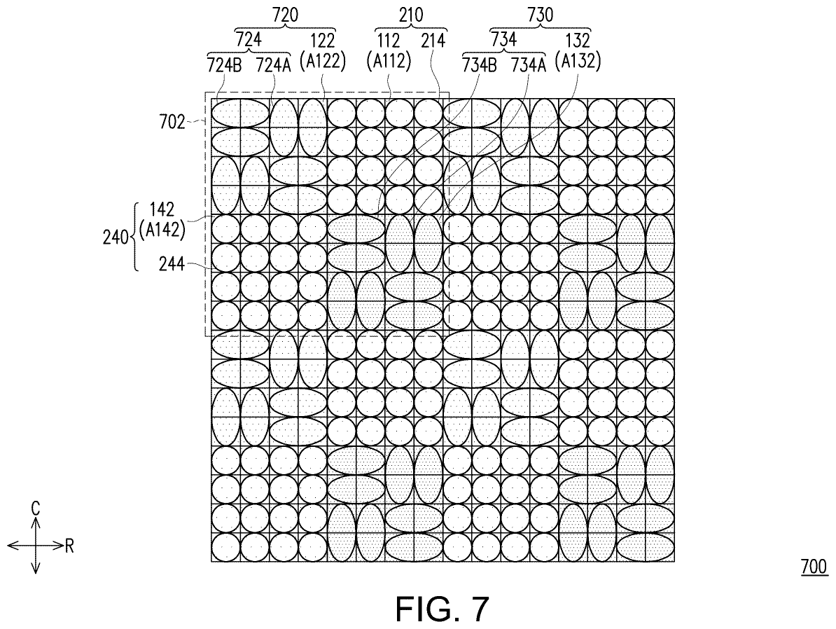

FIG. 7 is a schematic diagram of an image sensor in accordance with an embodiment of the disclosure. An image sensor 700 shown in FIG. 7 includes a plurality of repeating unit 702 and each repeating unit 702 includes a first pixel group 210, a second pixel group 720, a third pixel group 730 and a fourth pixel group 240 arranged in a 2×2 array. Each of the repeating unit 702 may be implemented by a Bayer pattern. For example, the first pixel group 210 and the four pixel group 240 diagonally arranged are used to generate the color data of green, while the second pixel group 720 and the third pixel group 730 diagonally arranged are used to generate the color data of blue and red, respectively. In the embodiment, the first pixel group 210 and the fourth pixel group 240 are implemented by the same design as the first pixel group 210 and the fourth pixel group 240 depicted in FIG. 2. For example, referring to the previous embodiment, the first pixel group 120 includes a first photodiode array A112 and first microlenses 214 and the fourth pixel group 240 includes a fourth photodiode array A142 and fourth microlenses 244, in which the photodiodes and the microlenses are arranged in a one-to-one configuration. The designs and the dispositions of the first pixel group 210 and the fourth pixel group 240 may refer to the previous description and be not reiterated herein.

The second pixel group 720 includes a second photodiode array A122 and second microlenses 724. The second photodiode array A122 includes 16 photodiodes 122 configured to generate second color data representing a color such as blue in the embodiment. Each of the second microlenses 724 has an elongated shape in the top view and covers 2 of the photodiodes 122 in the second photodiode array A122. In some embodiments, the photodiodes 122 under one of the second microlenses 724 may be binned to generate the color data. The second microlenses 724 may be oriented in two or more orientations. For example, a first portion of the second microlenses 724, such as the second microlenses 724A, is oriented in parallel to the column direction C and a second portion of the second microlenses 724, such as the second microlenses 724B, is oriented in parallel to the row direction R. In addition, in the embodiment, two of the second microlenses 724A are grouped and two groups of the second microlenses 724A are diagonally arranged in the second pixel group 720. For example, two groups of the second microlenses 724A are included in the second pixel group 720 and respectively located at the upper-right portion and the lower-left portion of the second pixel group 720. Simultaneously, two of the second microlenses 724B are grouped and two groups of the second microlenses 724B are diagonally arranged in the second pixel group 720. The two groups of the second microlenses 724B are located at, for example, the upper-left portion and the lower-right portion of the second pixel group 720. Accordingly, in the row direction R, one group of the second microlenses 724A is next to one group of the second microlenses 724B and in the column direction C, one group of the second microlenses 724A is also next to one group of the second microlenses 724B. In other words, the second microlenses 724A and the second microlenses 724B are alternately arranged in both the row direction R and the column direction C.

The third pixel group 730 includes a third photodiode array A132 and third microlenses 734. The third photodiode array A132 includes 16 photodiodes 132 arranged in a 4×4 array and each of the third microlenses 734 is disposed overlaying p of the photodiodes 132 in the third photodiode array A132. Herein, p is 2 such that each of the third microlenses 734 has an elongated shape in the top view and shared by two photodiodes 132. The arrangement of the third microlenses 734 is the same as the second microlenses 724. For example, a first portion of the third microlenses 734, such as the third microlenses 734A, is oriented in parallel to the column direction C, and a second portion of the third microlenses 734, such as the third microlenses 734B, is oriented in parallel to the row direction R. The first portion of the third microlenses 734 (the third microlenses 734A) and the second portion of the third microlenses 734 (the third microlenses 734B) may be grouped and arranged alternately in both the column direction C and the row direction R. For example, two of the third microlenses 734A oriented in parallel to the column direction C and two of the third microlenses 734B oriented in parallel to the row direction R are arranged in one column while the same two of the third microlenses 734A oriented in parallel to the column direction C and the other two of the third microlenses 734B oriented in parallel to the row direction R are arranged in one row.

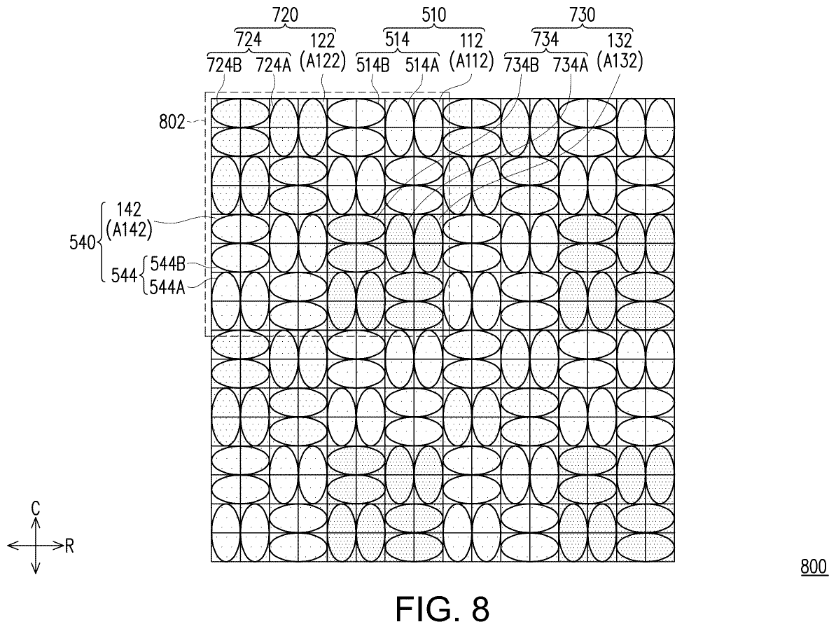

FIG. 8 is a schematic diagram of an image sensor in accordance with an embodiment of the disclosure. An image sensor 800 shown in FIG. 8 includes a plurality of repeating unit 802 and each repeating unit 802 includes a first pixel group 510, a second pixel group 720, a third pixel group 730 and a fourth pixel group 540 arranged in a 2×2 array. In the embodiment, the first pixel group 510 and the fourth pixel group 540 are implemented by the same design as the first pixel group 510 and the fourth pixel group 540 depicted in FIG. 5 and the second pixel group 720 and the third pixel group 730 are implemented by the same design as the second pixel group 720 and the third pixel group 730 depicted in FIG. 7. Specifically, the first pixel group 510 includes a first photodiode array A112 formed by 4×4 photodiodes 112 and first microlenses 514 with elongated shapes, the second pixel group 720 includes a second photodiode array A122 formed by 4×4 photodiodes 122 and second microlenses 724 with elongated shapes, the third pixel group 730 includes a third photodiode array A132 formed by 4×4 photodiodes 132 and third microlenses 734 with elongated shapes, and the fourth pixel group 540 includes a fourth photodiode array A142 formed by 4×4 photodiodes 142 and fourth microlenses 544 with elongated shapes.

In the embodiment, a first portion of the first microlenses 514 (the first microlenses 514A), a first portion of the second microlenses 724 (the second microlenses 724A), a first portion of the third microlenses 734 (the third microlenses 734A), and a first portion of the fourth microlenses 544 (the fourth microlenses 544A) are oriented in parallel to the column direction C. In addition, a second portion of the first microlenses 514 (the first microlenses 514B), a second portion of the second microlenses 724 (the second microlenses 724B), a second portion of the third microlenses 734 (the third microlenses 734B), and a second portion of the fourth microlenses 544 (the fourth microlenses 544B) are oriented in parallel to the row direction R. The arrangement of the first microlenses 514, the second microlenses 724, the third microlenses 734 and the fourth microlenses 544 may refer to the previous description accompanying with the contents of FIG. 5 and FIG. 7. The image sensor 800 having the elongated microlenses oriented in different direction enables PDAF in different directions while the resolution of the sensed image is slightly reduced since each elongated microlens is shared by two photodiodes.

In some alternative embodiments not shown in the drawings, an image sensor may be implemented by any combination selecting from one of the first pixel group 110, the first pixel group 210, the first pixel group 310, the first pixel group 410, and the first pixel group 510; one of the second pixel group 120, the second pixel group 120, the second pixel group 220, the second pixel group 620, and the second pixel group 720; one of the third pixel group 130, the third pixel group 230, the third pixel group 630, and the third pixel group 730; and one of the fourth pixel group 140, the fourth pixel group 240, the fourth pixel group 340, the fourth pixel group 440 and the fourth pixel group 540.

In view of the above, the image sensor in accordance with embodiments of the disclosure includes different microlens array overlaying the photodiode arrays to form different pixel groups. In at least one pixel group, a quantity of the microlenses is less than a quantity of the photodiodes generating the color data representing one color. In some embodiments, two or more photodiodes share one microlenses, which enables PDAF function. In some embodiments, one or more pixel group is implemented by arranging the microlenses and the photodiodes in a one-to-one configuration, which enables high resolution of the sensed image. The image sensor in accordance with the embodiments has both good image quality and PDAF performance.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An image sensor, comprising:
a first pixel group, comprising:
a first photodiode array comprising photodiodes to generate first color data; and
first microlenses, wherein each of the first microlenses is disposed overlaying n of the photodiodes in the first photodiode array; and
a second pixel group located next to the first pixel and comprising:
a second photodiode array comprising photodiodes to generate second color data representing a different color from the first color data; and
second microlenses, wherein each of the second microlenses is disposed overlaying m of the photodiodes in the second photodiode array, n and m are integers, and at least one of n and m is greater than 1.

2. The image sensor of claim 1, wherein m is different from n.

3. The image sensor of claim 1, wherein m and n are 2.

4. The image sensor of claim 3, wherein the first microlenses and the second microlenses are arranged in a same configuration.

5. The image sensor of claim 1, wherein n is 4 and each of the first microlenses has an isotropic shape in a top view.

6. The image sensor of claim 1, wherein n is 2, and each of the first microlenses has an elongated shape in a top view.

7. The image sensor of claim 6, wherein the first microlenses are oriented in parallel with each other.

8. The image sensor of claim 6, wherein a first portion of the first microlenses is oriented in parallel to a row direction and a second portion of the first microlenses is oriented in parallel to a column direction.

9. The image sensor of claim 8, wherein the first portion of the first microlenses and the second portion of the first microlenses are alternately arranged in the row direction and the column direction.

10. The image sensor of claim 8, wherein the first portion of the first microlenses and the second portion of the first microlenses are arranged in different columns.

11. The image sensor of claim 1, wherein m is 1 and n is greater than 1.

12. The image sensor of claim 1, further comprising a third pixel group located next to the first pixel and the second pixel group and the third pixel group being arranged at different sides of the first pixel group, wherein the third pixel group comprises:
a third photodiode array comprising photodiodes to generate third color data representing a different color from the first color data and the second color data;
third microlenses, wherein each of the third microlenses is disposed overlaying m of the photodiodes in the third photodiode array.

13. The image sensor of claim 12, wherein the third microlenses and the second microlenses are arranged in a same configuration.

14. The image sensor of claim 1, further comprising a third pixel group located next to the second pixel group, wherein the third pixel group comprises:
a third photodiode array comprising photodiodes to generate third color data representing a same color as the first color data;
third microlenses, wherein each of the third microlenses is disposed overlaying n of the photodiodes in the third photodiode array.

15. The image sensor of claim 14, wherein n is 2, and each of the first microlenses and the third microlenses has an elongated shape in a top view.

16. The image sensor of claim 15, wherein the first microlenses are oriented in parallel with a row direction, and the third microlenses are oriented in parallel with a column direction.

17. The image sensor of claim 14, wherein the first microlenses and the third microlenses are arranged in a same configuration.

18. The image sensor of claim 14, wherein the first microlenses and the third microlenses are arranged in different configurations.

19. The image sensor of claim 1, wherein each of the first photodiode array and the second photodiode array comprises 16 photodiodes arranged in a 4×4 array.

20. The image sensor of claim 1, wherein the first color data represents green and the second color data represents blue or red.
